(19) United States
(12) Patent Application Publication
(10) Pub. No.: US 2026/0326157 A1
(43) Pub. Date: Oct. 22, 2026

(54) LIQUID SUPPLY DEVICE AND SUBSTRATE CLEANING METHOD

(71) Applicant: ACM RESEARCH (SHANGHAI), INC., Shanghai (CN)

(72) Inventors: Xinping Deng, Shanghai (CN); Xiongfei Wei, Shanghai (CN); Hui Wang, Shanghai (CN); Jian Wang, Shanghai (CN); Shena Jia, Shanghai (CN); Yang Han, Shanghai (CN); Wenjun Wang, Shanghai (CN); Xiaoyan Zhang, Shanghai (CN)

(73) Assignee: ACM RESEARCH (SHANGHAI), INC., Shanghai (CN)

(21) Appl. No.: 19/105,778

(22) PCT Filed: Jun. 27, 2023
(86) PCT No.: PCT/CN2023/102584

§ 371 Date: Feb. 21, 2025

(30) Foreign Application Priority Data
Aug. 22, 2022 (CN) 202211007381.7

(51) Int. Cl. B08B 3/02; B05B 7/04; B08B 3/08; H10P 72/00

(52) U.S. Cl. CPC B08B 3/02; B05B 7/0408; B08B 3/08; H10P 72/0414; H10P 72/0448; H10P 72/0604

(57) ABSTRACT

The present invention proposes a liquid supply device and a substrate cleaning method. The liquid supply device includes a nozzle. A plate-shaped separating section or a cylinder-shaped separating section may be provided above the liquid outlet of the nozzle. The interior of the nozzle can adopt the structure of an upper chamber and a lower chamber, and both the upper chamber and lower chamber are configured with exhaust ports. Both the upper chamber and lower chamber are configured with liquid inlets. The liquid supply device further includes a controller and a liquid level sensor. The controller regulates the opening degree of the regulating valve on the exhaust line of the nozzle according to the liquid level detection signal in the nozzle obtained from the liquid level sensor. The method is conducive to reducing flow fluctuation when the nozzle is supplied with liquid to the substrate.

### FIELD OF THE INVENTION

The present invention relates to the field of semiconductor equipment, and more particularly to a liquid supply device and a substrate cleaning method.

### BACKGROUND

The chip manufacturing process has a large number of cleaning steps for the removal of high polymers. SPM (a mixture of H₂SO₄ and H₂O₂) is commonly used to remove the high polymers. The mixture of H₂SO₄ and H₂O₂ forms caloric acid, which is a very strong oxidizing agent that reacts quickly with the organic residues on the wafer surface to form H₂SO₄, CO₂, and H₂O, resulting in the rapid removal of the organic residues from the wafer surface.

The temperature and volume ratio of SPM are the two main factors that determine the removal efficiency of organic matter. In a single wafer SPM process, H₂SO₄ and H₂O₂ are usually mixed in the supply line, or H₂SO₄ and H₂O₂ are mixed in the supply nozzle to obtain higher reaction temperature and reaction activity.

Due to the decomposition of H2O₂ when exposed to high temperature H₂SO₄, O₂ is produced. The mixture of H₂SO₄ and H2O₂ is an exothermic reaction, and the temperature of SPM can usually reach 180° C.~220° C. after the mixture, which will cause part of the mixture to vaporize. The oxygen generated by decomposition and the steam generated by high temperature vaporization will cause the sprayed SPM to carry gas masses, which will easily cause the liquid to splash, affecting the stability and uniformity of the liquid supply.

### SUMMARY

The aim of the present invention is to provide a liquid supply device and a substrate cleaning method for solving the problem of how to realize stable liquid supply of the gas-containing liquid in the prior art.

In order to realize the above aim and other related aims, the present invention provides a liquid supply device comprising a nozzle having a cavity inside, the nozzle comprising:

a liquid inlet, for introducing liquid into the cavity;

a liquid outlet, provided in a lower portion of the cavity, for discharging liquid from the cavity;

an exhaust port, provided in an upper portion of the cavity, for discharging gas from the cavity;

a separating section, in the shape of a cylinder, located above the liquid outlet and located in the cavity, the separating section comprising a cylinder body with a plurality of slanted holes being provided on the sidewall of the cylinder body, the plurality of slanted holes being provided at an inclined upward direction when viewed from the inner side of the cylinder body to the outer side, and the bottom of the cylinder body being open and connected to the liquid outlet.

The present invention also provides another liquid supply device comprising a nozzle having a cavity inside, the nozzle comprising:

a first liquid inlet, tangential to the sidewall of the cavity, for enabling the first liquid to enter the cavity of the nozzle in a tangential direction;

a second liquid inlet, tangential to the sidewall of the cavity, for enabling the second liquid to enter the cavity of the nozzle in a tangential direction, the first liquid and the second liquid rotating in the same direction after entering the cavity;

a liquid outlet, provided in a lower portion of the cavity, for discharging a mixture of the first liquid and the second liquid from the cavity;

an exhaust port, provided in an upper portion of the cavity, for discharging gas from the cavity.

The present invention also provides another liquid supply device comprising a nozzle having a cavity inside, the nozzle comprising:

a mixture liquid inlet, tangential to the sidewall of the cavity, for enabling a mixture of at least two kinds of liquid to enter the cavity of the nozzle in a tangential direction;

a liquid outlet, provided in a lower portion of the cavity, for discharging the mixture from the cavity;

an exhaust port, provided in an upper portion of the cavity, for discharging gas from the cavity.

The present invention also provides another liquid supply device comprising a nozzle having an upper chamber and a lower chamber inside, wherein,

the upper chamber comprises:

an upper liquid inlet, for introducing the liquid into the upper chamber;

an upper exhaust port, provided in an upper portion of the upper chamber, for discharging gas from the upper chamber;

an upper liquid outlet, provided between the upper chamber and the lower chamber, for introducing the liquid in the upper chamber into the lower chamber;

the lower chamber comprises:

a lower exhaust port, provided in an upper portion of the lower chamber, for discharging gas from the lower chamber;

a lower liquid outlet, provided in a lower portion of the lower chamber, for discharging liquid from the lower chamber.

As described above, the present invention provides a liquid supply device having the following beneficial effects:
(1) A plate-shaped separating section or a cylinder-shaped separating section is provided above the liquid outlet of the nozzle for gas-liquid separation. The cylinder-shaped separating section relies on a plurality of slanted holes provided on the sidewall of the cylinder body, so that gas-liquid separation is achieved under the hindering effect of the slanted holes when the liquid flows from the outside of the cylinder body to the inside of the cylinder body;
(2) The liquid inlets of the nozzle adopt a tangential liquid intake method, using centrifugal force to promote gas-liquid separation so that the gas in the nozzle is quickly discharged to achieve stable liquid supply;
(3) The controller regulates the opening degree of the regulating valve on the exhaust lines of the nozzle according to the liquid level detection signal in the nozzle obtained from the liquid level sensor, so as to maintain the stability of liquid level in the nozzle, which is conducive to reducing the flow fluctuation when the nozzle is supplied with the liquid to the substrate, improving the uniformity and reliability of the liquid treatment;
(4) The inside of the nozzle adopts the structure of an upper chamber and a lower chamber, and the upper chamber and lower chamber are equipped with exhaust ports, which can realize the secondary exhaust;
(5) The inside of the nozzle adopts the structure of an upper chamber and a lower chamber, and the upper chamber and lower chamber are equipped with liquid inlets, so that the treatment liquid can be mixed twice. Compared to the treatment liquid mixed once, the gas amount and generation rate may be reduced, which will make the bubbles discharge smoother;
(6) The inside of the nozzle adopts the structure of an upper chamber and a lower chamber, and the exhaust port of the upper chamber is connected to a negative pressure generator. Corresponding to the SPM cleaning process, after the upper chamber stops liquid intake, the pressure in the upper chamber is reduced and the residual liquid in the upper chamber can be discharged to the lower chamber slowly. When switching from the mixture supply stage of H₂SO₄ and H₂O₂ to the supply stage of H₂O₂, the switch progress is smoother and avoids the turbulence of the liquid flow caused by the sudden increase in the concentration of H₂O₂ in the lower chamber.

### BRIEF DESCRIPTION OF THE DRAWINGS

The features and performances of the present invention are further described by the following embodiments and accompanying drawings.

FIG. 1 shows a schematic diagram of the overall structure of the substrate processing apparatus;

FIG. 2 shows a schematic diagram of the structure of the liquid supply device and the nozzle in embodiment 1 of the present invention;

FIG. 3 shows a partially enlarged view at position A in FIG. 2;

FIG. 4(a) to 4(d) show schematic diagrams of different structures of the cylinder body;

FIG. 5 shows a schematic diagram of the structure of another liquid supply device and the nozzle in embodiment 1 of the present invention;

FIG. 6(a) and FIG. 6(b) show schematic diagrams of the structures of the liquid supply device and the nozzle in embodiment 2 of the present invention;

FIG. 7 shows a schematic diagram of the structure of the liquid supply device and the nozzle in embodiment 3 of the present invention, wherein the nozzle is substantially cylindrical in shape, having a first liquid inlet and a second liquid inlet;

FIG. 8 shows a cross-sectional view in the A-A direction in FIG. 7;

FIG. 9 shows a top view of the nozzle in embodiment 3 of the present invention;

FIG. 10 shows a sectional three-dimensional view in the B-B direction in FIG. 9, wherein the separating section is a plate-shaped separating section;

FIG. 11 shows another sectional three-dimensional view in the B-B direction in FIG. 9, wherein the separating section is a cylinder-shaped separating section;

FIG. 12 shows a schematic view of the structure of another liquid supply device and the nozzle in embodiment 3 of the present invention, wherein the nozzle is substantially conical in shape with mixture liquid inlets;

FIG. 13 shows a schematic diagram of the structure of the liquid supply device and the nozzle in embodiment 4 of the present invention;

FIG. 14 shows a schematic diagram of the structure of another liquid supply device and the nozzle in embodiment 4 of the present invention;

FIG. 15 shows a schematic diagram of the structure of another liquid supply device and the nozzle in embodiment 4 of the present invention;

FIG. 16 shows a schematic diagram of the structure of another liquid supply device and the nozzle in embodiment 4 of the present invention;

FIG. 17 shows a schematic diagram of the structure of the liquid supply device and the nozzle in embodiment 5 of the present invention;

FIG. 18 shows a schematic diagram of the structure of the liquid supply device and the nozzle in embodiment 6 of the present invention; and

FIG. 19 shows a timing diagram of the turning-on and turning-off of the liquid inlet valve of the nozzle and a timing diagram of the proportion of the mixture liquid inlets within the lower chamber in embodiments 5 and 6 of the present invention.

### PREFERRED EMBODIMENTS OF THE INVENTION

The following illustrates the embodiments of the present invention by means of specific and concrete embodiments, and other advantages and effects of the present invention can be readily understood by those skilled in the art from the contents disclosed in this specification. The present invention may be implemented or applied in various other specific embodiments. The details in this specification may be modified or altered in various ways based on different views and applications without departing from the spirit of the present invention.

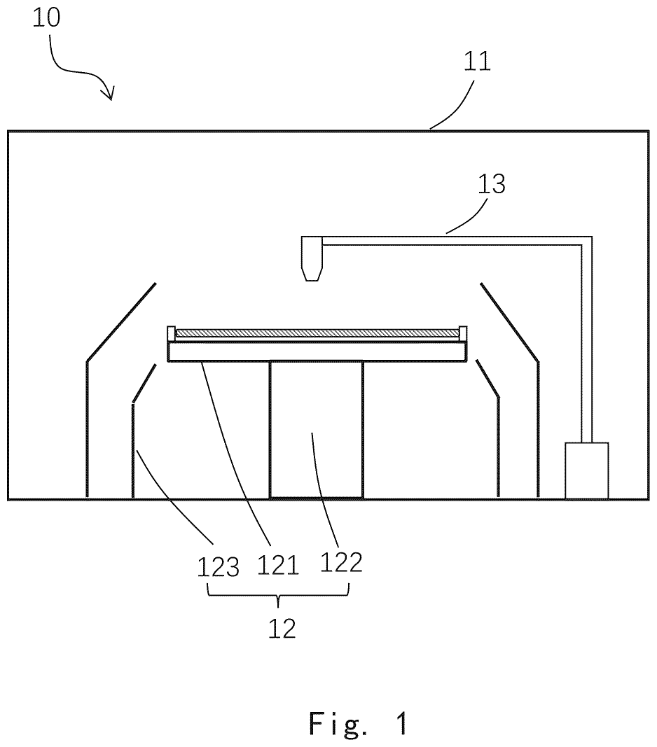

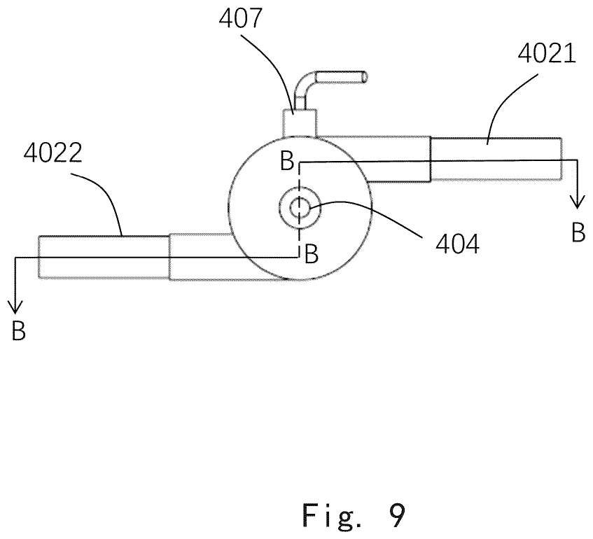

Please refer to FIGS. 1 to 19. It should be noted that the illustrations provided in the embodiments are only schematic to illustrate the basic concepts of the present invention. Although the illustrations only show the components related to the present invention and are not drawn in accordance with the numbers, shapes, and sizes of the components in actual implementation, the actual implementation of the components of the forms, numbers, and proportions may be an arbitrary change, and the layouts of the components may be more complex.

As shown in FIG. 1, the substrate processing apparatus 10 includes a chamber 11, a substrate holding device 12, and a liquid supply device 13. The substrate holding device 12 is located within the chamber 11 and is used to hold and rotate the substrate. The substrate holding device 12 is typically configured with a carrier table 121 for holding the substrate. The rotating shaft 122 is used to rotate the carrier table 121. A collection cup 123 is provided at the periphery of the carrier table 121 for recovering the treatment liquid. The liquid supply device 13 is used to provide the treatment liquid to the substrate for liquid treatment of the substrate.

Commonly used treatment liquid includes SC-1, SC-2, DHF, SPM, high-temperature phosphoric acid solution, and so on. Among them, SPM and high-temperature phosphoric acid solution usually entrain gas in the process of supplying the liquid. If the gas is not discharged in time and ejected from the nozzle together with the treatment liquid, the gas will cause the liquid to splash and affect the stability of the liquid supply. With respect to a liquid supply device for supplying the treatment liquid with entrained gas, the present invention improves the stability of the liquid supply by changing the nozzle structure of the liquid supply device, so that the gas in the treatment liquid can be discharged timely before the treatment liquid is supplied to the substrate. The liquid supply device with different nozzle structures is described below.

### First Embodiment

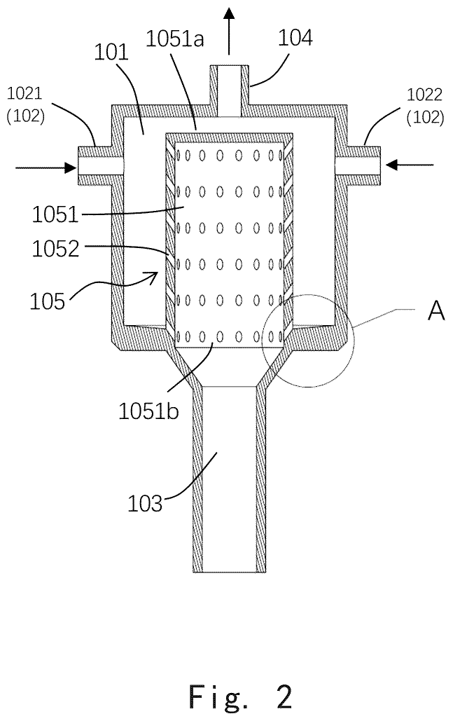

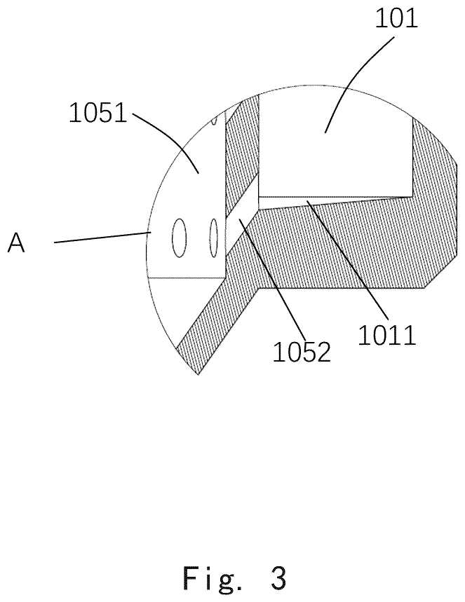

Referring to FIGS. 2 and 3, this embodiment proposes a liquid supply device comprising a nozzle for supplying the treatment liquid to the substrate, such as SPM, which is entrained with gas that affects the stability of fluid supply. The nozzle has a cavity 101 inside, and the nozzle further has a liquid inlet 102 for introducing liquid into the cavity 101. A liquid outlet 103 is provided in a lower portion of the cavity 101 for discharging liquid from the cavity 101. An exhaust port 104 is provided in an upper portion of the cavity 101 for discharging gas from the cavity 101.

It should be noted that the liquid inlet 102 may introduce at least one kind of liquid into the cavity 101. Each kind of liquid may be configured with separate liquid inlets, or a mixture of at least two kinds of liquid may be introduced into the cavity 101 by a single liquid inlet.

In this embodiment, the liquid inlet 102 is used to introduce two kinds of liquid into the cavity 101, noted as the first liquid and the second liquid respectively. For example, the first liquid may be H₂O₂, and the second liquid may be H₂SO₄.

In the embodiment illustrated in FIG. 2, each kind of liquid is configured with a separate inlet, specifically, the liquid inlet 102 comprises a first liquid inlet 1021 and a second liquid inlet 1022. The first liquid inlet 1021 is used to introduce the first liquid into the cavity 101, and the second liquid inlet 1022 is used to introduce the second liquid into the cavity 101. The first liquid and the second liquid are mixed in the cavity 101. It will be appreciated that in other embodiments, each kind of liquid may also be configured with two or more separate liquid inlets. For example, the first liquid inlet 1021 may be provided with two or more, for introducing the first liquid into the cavity 101. The second liquid inlet 1022 may be provided with two or more, for introducing the second liquid into the cavity 101.

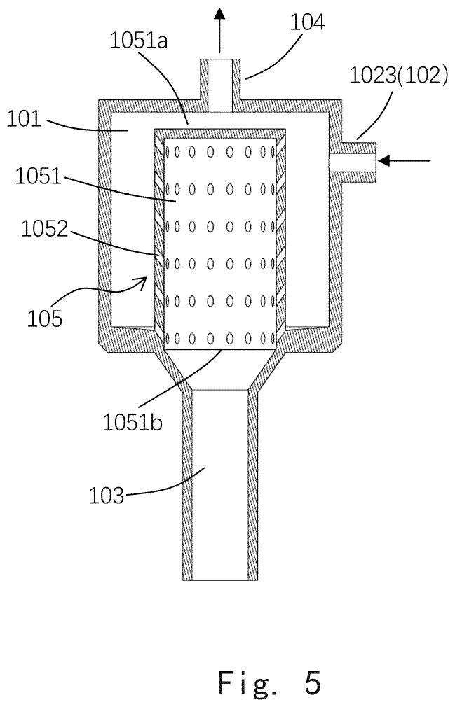

In the embodiment shown in FIG. 5, a mixture of at least two kinds of liquid is introduced into the cavity 101 through a liquid inlet. Specifically, the liquid inlet 102 includes a mixture liquid inlet 1023 for introducing a mixture of the first liquid and the second liquid into the cavity 101. The illustration in FIG. 5 is only an example and is not intended to limit the number of mixture liquid inlet 1023, that is, the mixture liquid inlet 1023 may be provided with two or more. The first liquid and the second liquid may be supplied to the cavity 101 of the nozzle after being mixed in the liquid supply line outside the nozzle. In addition, a mixer may be provided on the supply line, where the first liquid and the second liquid are mixed and then supplied to the cavity 101 of the nozzle.

It should be noted that, depending on the process requirement, the liquid inlet 102 can also be configured with both a separate liquid inlet for supplying one kind of liquid and a liquid inlet for supplying a mixture of at least two kinds of liquid. For example, the liquid inlet 102 is simultaneously configured with a first liquid inlet 1021, a second liquid inlet 1022 and a mixture liquid inlet 1023.

A cylindrical separating section 105 is provided above the liquid outlet 103, and the separating section 105 is located in the cavity 101 and is used to achieve gas-liquid separation. Specifically, the separating section 105 comprises a cylinder body 1051, and a plurality of slanted holes 1052 are provided on the sidewall of cylinder body 1051. The bottom 1051b of the cylinder body 1051 is open and connected to the liquid outlet 103. When viewed from the inside of the cylinder body 1051 to the outside, the slanted holes 1052 on the sidewall of the cylinder body 1051 are inclined upwardly, and the angle between the slanted holes 1052 and the vertical direction is from 15° to 75°, for example, from 30° to 60°. It should be noted that the shape of the cylinder body 1051 is not limited to the cylindrical shape shown in FIG. 2, but may also be cone-shaped, square tube-shaped, prism-shaped. In other words, the cross-section of the cylinder body 1051 may be polygonal, rounded, oval, or any other shape, and is not specifically limited herein.

When the first liquid and the second liquid are supplied to the cavity 101 of the nozzle, the first liquid and second liquid enter the outer region of the cylinder body 1051 firstly, and then enter the inner side of the cylinder body 1051 through the slanted holes 1052 on the sidewall of the cylinder body 1051. When the liquid flows into the inner side of the cylinder body 1051 along the slanted holes 1052 at an inclined downward angle, the vast majority of the gas floats upward due to the resistance of the slanted holes 1052 and is unable to enter the inner side of the cylinder body 1051. The gas escapes from the liquid through the exhaust port 104 and is discharged from the cavity 101. The gas-liquid separation is completed, so as to reduce the gas content in the mixture and improve the stability of the liquid supply.

FIG. 3 shows a partially enlarged view of position A in FIG. 2. The bottom of the cavity 101 in the nozzle is provided with a deflector surface 1011, which is inclined downward towards the direction of the cylinder body 1051. Specifically, the deflector surface 1011 is inclined downward towards the wall of the cylinder body 1051 along the wall of the nozzle. The lowest row of slanted holes 1052 on the cylinder body 1051 are connected to the lowest point of the deflector surface 1011, so as to avoid liquid build-up in the nozzle.

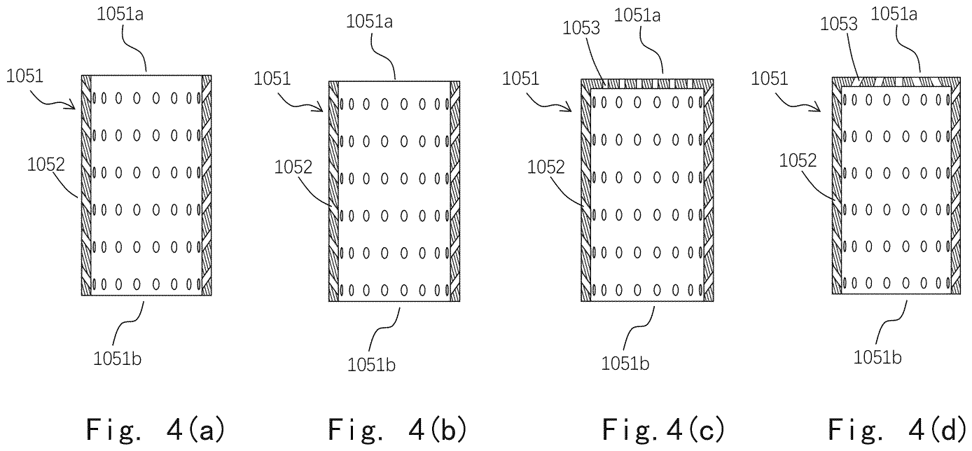

The structure of the top 1051a of the cylinder body 1051 may be varied as follows, and schematic diagrams of cylinder body with different top structures are shown in FIG. 4(a) to 4(d).

As shown in FIG. 4(a), the top 1051a of the cylinder body 1051 is sealed.

As shown in FIG. 4(b), the top 1051a of the cylinder body 1051 is open. If part of the gas is coerced by the liquid into the inner side of the cylinder body 1051, the gas in the inner side of the cylinder body 1051 can be discharged upwardly through the opening on top of 1051a and is discharged from the nozzle by the exhaust port 104, further reducing the gas content in the mixture and improving the stability of the liquid supply.

As shown in FIG. 4(c), the top 1051a of the cylinder body 1051 is provided with at least one through-hole 1053. The gas in the cylinder body 1051 can be discharged from the cylinder body 1051 by the through-hole 1053 on top 1051a of the cylinder body 1051, and then discharged from the nozzle by the exhaust port 104.

In FIG. 4(c), the top 1051a of the cylinder body 1051 is provided with a number of through-holes 1053, which may be vertical through-holes 1053. In FIG. 4(d), the top 1051a of the cylinder body 1051 is provided with a number of through-holes 1053, which are inclined towards the exhaust port 104, so that the gas in the cylinder body 1051 is discharged from the through-holes 1053 and converges towards the exhaust port 104, facilitating the rapid discharge of gas bubbles. In order to cause the gas in the cylinder body 1051 to converge towards the exhaust port 104, the top 1051a of the cylinder body 1051 may be provided in the shape of a herringbone or an arch.

### Second Embodiment

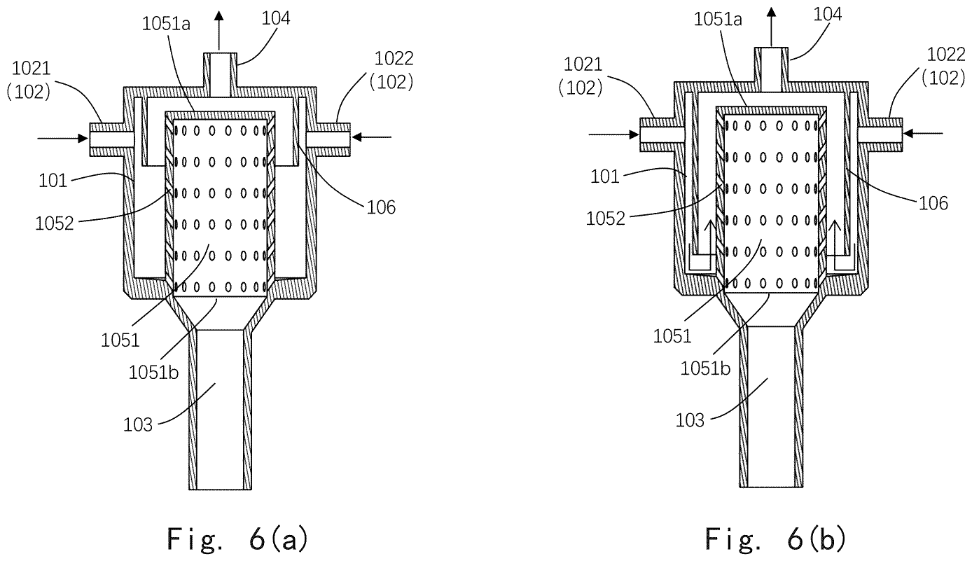

Referring to FIGS. 6(a) and 6(b), the present embodiment provides a liquid supply device. The difference of the present embodiment as compared to embodiment 1 is that a buffer plate 106 is provided in the cavity 101 to block the liquid inlet 102, and there is a gap between the buffer plate 106 and the liquid inlet 102. The buffer plate 106 may be provided near the liquid inlet 102 as shown in FIG. 6(a). In this embodiment, the buffer plate 106 is provided between the cylinder body 1051 and the liquid inlet 102 to block the liquid inlet 102, to buffer and block the liquid introduced through the liquid inlet 102, to reduce the flow rate of the liquid, to prevent the liquid with entrained gas enters the cavity 101 and then directly impacts and enters the inner side of the cylinder body 1051 before being discharged through the liquid outlet 103, so as to reduce gas content in the liquid ejected from the liquid outlet 103 and achieve a stable liquid supply.

In addition, the buffer plate 106 is not only used to block the liquid inlet 102, but also used to restrict the flow direction of the liquid entering the cavity 101. Specifically, as shown in FIG. 6(b), the buffer plate 106 is provided in the cavity 101 to block the liquid inlet 102. The buffer plate 106 extends along the axial direction of the cylinder body 1051, so that the liquid entering the cavity 101 by the liquid inlet 102 flows from bottom to top on the outside of the cylinder body 1051 (shown by the arrows in FIG. 6(b)).

It should be noted that in embodiment 2, the same structure as in embodiment 1 is attached with the same accompanying drawing designations, and the description is omitted.

### Third Embodiment

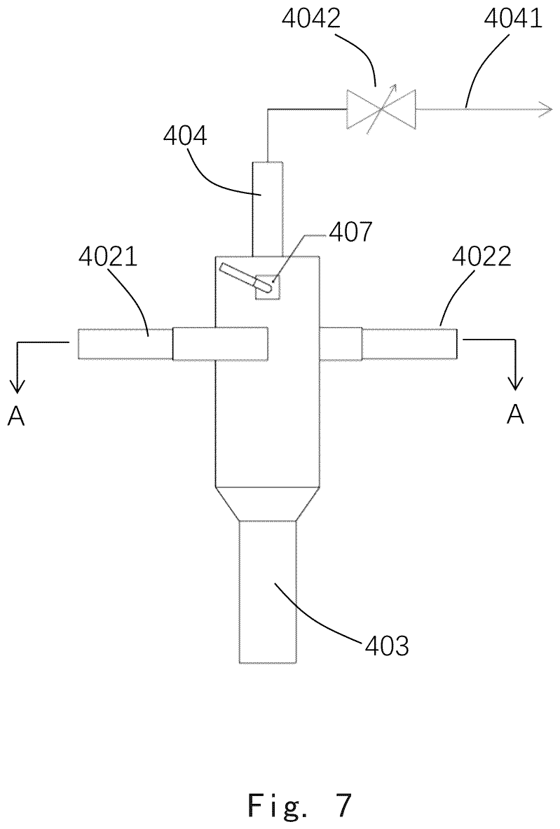

Referring to FIGS. 7 to 12, this embodiment provides a liquid supply device comprising a nozzle for supplying the treatment liquid to a substrate surface. The treatment liquid is entrained with the gas, such as SPM, which affects the stability of liquid supply. The nozzle has a cavity 401 inside, further comprising liquid inlets being tangential to the sidewall of the cavity 401 for allowing the liquid to enter the nozzle in a tangential direction. The liquid exit 403 is provided in a lower portion of the cavity 401 for discharging liquid from the nozzle. The vent 404 is provided in an upper portion of the cavity 401 for discharging gas from the nozzle.

It is noted that the liquid inlets may introduce at least one kind of liquid into the cavity 401, and each kind of liquid may be configured with a separate liquid inlet, or a mixture of at least two kinds of liquid may be introduced into the cavity 401 through a single liquid inlet.

In this embodiment, the liquid inlets are used to introduce two kinds of liquid into the cavity 401, which are recorded as the first liquid and the second liquid, for example, the first liquid may be H₂O₂, and the second liquid may be H₂SO₄.

The two ways of setting up the liquid inlets will be explained below using the embodiments of introducing the first liquid and the second liquid into the cavity 401.

### Liquid Inlet Setup Method 1

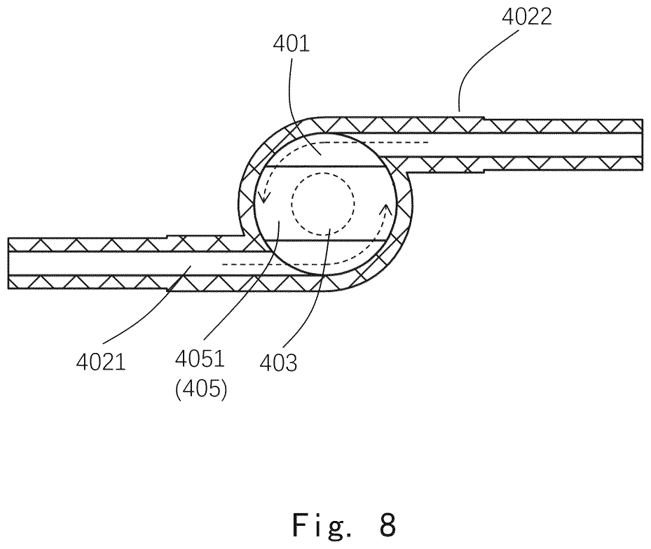

Each kind of liquid is configured with a separate liquid inlet, as shown in FIGS. 7 and 8, and the liquid inlets include a first liquid entry 4021 and a second liquid entry 4022. The first liquid entry 4021 is tangential to the sidewall of the cavity 401 for allowing the first liquid to enter the nozzle in a tangential direction. The second liquid entry 4022 is tangential to the sidewall of the cavity 401 for allowing the second liquid to enter the nozzle in a tangential direction. As shown by the dashed arrows in FIG. 8, the first liquid and the second liquid are in the same direction of rotation after entering the nozzle.

### Liquid Inlet Setup Method 2

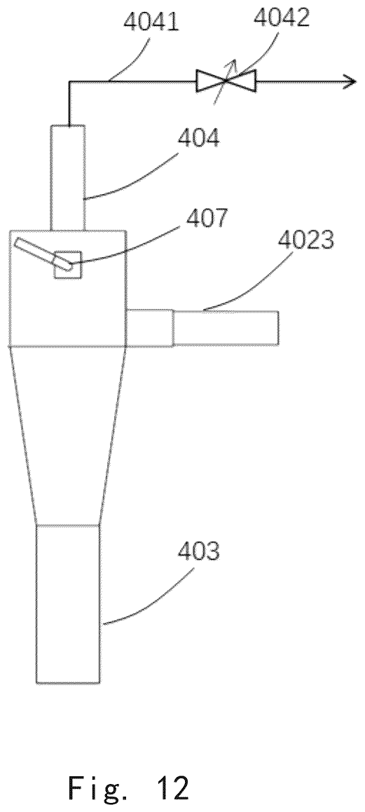

As shown in FIG. 12, a mixture of at least two kinds of liquid is introduced into the cavity 401 through a liquid inlet. The liquid inlet comprises a mixture liquid entry 4023, which is tangential to the sidewall of the cavity 401 for allowing the mixture of the first liquid and the second liquid to enter the nozzle in a tangential direction. The first liquid and the second liquid may be supplied into the cavity 401 of the nozzle after being mixed in the liquid supply line external to the nozzle. In addition, a mixer may be provided on the supply line, where the first liquid and the second liquid are mixed and then supplied to the cavity 401 of the nozzle.

In addition, according to the process requirements, the liquid inlet can also be simultaneously equipped with the first liquid entry 4021, the second liquid entry 4022 and the mixture liquid entry 4023. In this embodiment, the liquid inlets adopt a tangential liquid intake method, wherein the liquid enters the cavity 401 and forms a rotational movement along the wall of the cavity 401. The tangential liquid intake method facilitates better mixture of the first liquid and the second liquid on the one hand. On the other hand, the centrifugal force generated by the rotational movement of the liquid can be relied upon to achieve gas-liquid separation and reduce the gas content in the liquid discharged from the nozzle. The shape of the cavity 401 can be roughly cylindrical (as shown in FIG. 7) or roughly conical (as shown in FIG. 12), wherein the cavity 401 is conical to promote the rotational movement of the liquid in the cavity 401, which is more conducive to gas-liquid separation.

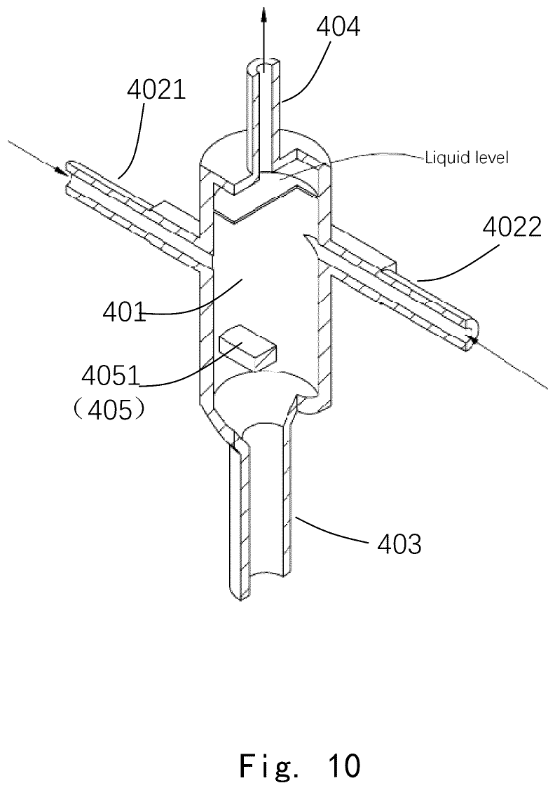

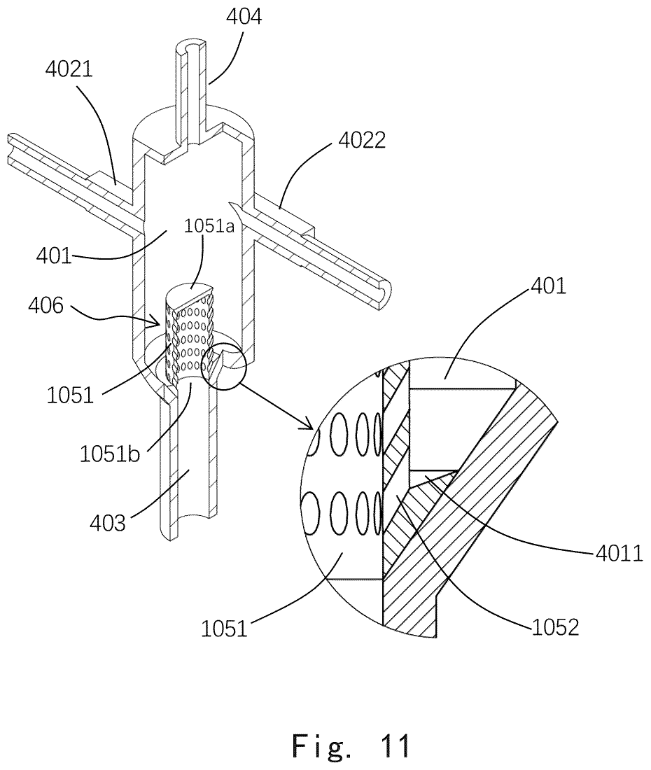

The cavity 401 is provided with a separating section, which is located above the liquid exit 403, for intercepting and separating bubbles in the liquid and reducing the gas content in the liquid discharged from the nozzle. FIGS. 10 and 11 illustrate two different structures of separating sections, notated as plate-shaped separating section 405 and cylinder-shaped separating section 406, and the two structures of separating sections will be described one by one hereinafter.

### Plate-shaped Separating Section 405

As shown in FIG. 10, the separating section 405 is in the form of a plate, comprising a plate body 4051 disposed above the liquid exit 403. The plate body 4051 is spaced apart from the liquid exit 403 in the height direction. When viewed from top to bottom, the plate body 4051 at least partially blocks the liquid exit 403, thereby playing a certain role in intercepting and separating bubbles trapped in the liquid, and preventing bubbles from being discharged with the liquid from the liquid exit 403. In this embodiment, as shown in FIG. 8, the plate body 4051 is oriented towards the liquid exit 403 and completely covers the liquid exit 403. A gap exists between a portion of the edge of the plate body 4051 and the inner wall of the cavity 401, which serves as a flow path for liquid circulation, so that liquid within the cavity 401 bypasses the plate body 4051 and is discharged through the liquid exit 403.

### Cylinder-shaped Separating Section 406

As shown in FIG. 11, the separating section 406 is in the shape of a cylinder comprising a cylinder body 1051. A plurality of slanted holes 1052 are provided on the sidewall of the cylinder 1051. The bottom 1051b of the cylinder body 1051 is open and connected to the liquid exit 403. The top 1051a of the cylinder body 1051 may have a number of different configurations, as can be seen in FIGS. 4(a) to 4(d). The top 1051a of the cylinder body 1051 is sealed (as shown in FIG. 4(a)) or open (as shown in FIG. 4(b)). Besides, the top 1051a of the cylinder body 1051 is provided with at least one through-hole 1053 (as shown in FIG. 4(c) and FIG. 4(d)), which is either a vertical hole or the through-hole 1053 slanted towards the vent 404.

Preferably, the top of the cylinder body 1051 is located below the liquid inlets to reduce the interference of the cylinder body with the rotational movement of the liquid.

When the separating section adopts the cylinder-shaped separating section 406, in order to avoid the accumulation of liquid in the cavity 401, the bottom of the cavity 401 is provided with a guiding surface 4011, as shown in the partially enlarged view in FIG. 11. The guiding surface 4011 is slanted downwardly along the nozzle wall towards the direction of the wall surface of the cylinder body 1051, so that the guiding surface 4011 can divert the liquid that accumulates at the bottom of the cavity 401 towards the root position of the cylinder body 1051. The lowest row of slanted holes 1052 on the cylinder body 1051 are connected to the lowest position of the guiding surface 4011. After the liquid flows to the root position of the cylinder body 1051, the liquid enters the inner side of the cylinder body 1051 through the slanted holes 1052 and is discharged by the liquid exit 403, which in turn can eliminate the problem of the liquid remaining in the region of the cavity 401 on the outer side of the cylinder body 1051.

Referring again to FIG. 7, in order to further achieve stable liquid supply, the liquid supply device is further configured with a liquid level sensor 407, an exhaust line 4041 and a controller. The liquid level sensor 407 is used to detect a liquid level height within the nozzle cavity 401. The exhaust line 4041 is connected to the vent 404 for discharging gas from the cavity 401, and the exhaust line 4041 is configured with a regulating valve 4042. The controller is connected to the liquid level sensor 407 and the regulating valve 4042 via signals, to form a closed-loop control so as to maintain the level of the liquid in the cavity 401 at a predetermined height. By stabilizing the liquid level in the nozzle at the predetermined height, the flow rate at the liquid exit 403 can be made approximately constant, resulting in better cleaning or etching results.

Specifically, when the liquid level sensor 407 detects that the liquid level in the cavity 401 is higher than the predetermined height and sends the signal to the controller, the controller sends an instruction that reduces the valve opening degree to the regulating valve 4042. When the liquid level sensor 407 detects that the liquid level in the cavity 401 is lower than the predetermined height and sends the signal to the controller, the controller sends an instruction that increases the valve opening degree to the regulating valve 4042.

The liquid level sensor 407 may employ a contact-type liquid level sensor, such as a differential pressure type liquid level sensor or a float type liquid level sensor, which may be fixedly disposed on the nozzle, as shown in FIG. 7. The liquid level sensor 407 may also employ a non-contact liquid level sensor, such as an optical liquid level sensor or a capacitive liquid level sensor.

In one embodiment, the predetermined height of the liquid level in the cavity 401 is set higher than the liquid inlets, so that fresh liquid supplied from the liquid inlets enters into the original liquid in the cavity 401, which can reduce the fluctuation of the liquid level and is conducive to maintaining the stability of liquid level, helping to realize the stable liquid supply.

In another embodiment, the predetermined height of the liquid level in the cavity 401 is set lower than the liquid inlets, so that the fresh liquid supplied by the liquid inlets enters the upper gas of the cavity 401. A part of the gas in the fresh liquid will not be involved in the liquid phase, and the part of the gas does not need to overcome the escape resistance at the gas-liquid interface, which will be conducive to separating the gas from the liquid and realizing a better exhaust effect.

It is worth stating that the preferred embodiment is one in which the predetermined level of liquid in the cavity 401 is controlled higher or lower than the liquid inlets. However, the predetermined height of the liquid level in the cavity 401 is not limited and can be reasonably set in combination with the process, the nozzle structure and other parameters. For example, the predetermined height of the liquid level in the cavity 401 can also be controlled at a height that is basically flush with the liquid inlets.

### Fourth Embodiment

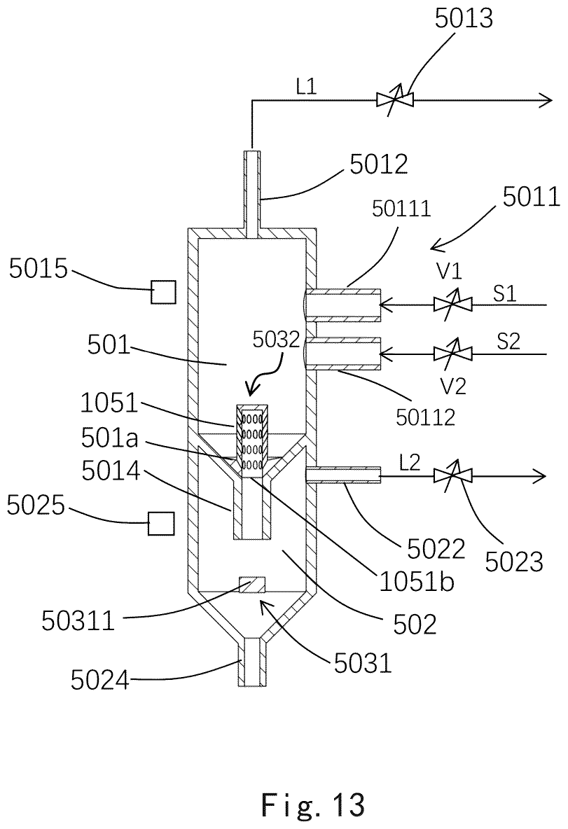

Referring to FIGS. 13 to 16, this embodiment provides a liquid supply device having a nozzle and a controller. The nozzle is hollow inside and is divided into an upper chamber 501 and a lower chamber 502. The structures of the upper chamber 501 and the lower chamber 502 will be described below in conjunction with FIGS. 13 to 16 of the accompanying drawings.

### Upper Chamber 501

The upper chamber 501 is provided with an upper liquid inlet 5011, an upper exhaust port 5012, an upper liquid outlet 5014, and an upper liquid level sensor 5015.

The upper liquid inlet 5011 is connected to the liquid supply line for introducing liquid into the upper chamber 501. The upper liquid inlet 5011 may introduce at least one kind of liquid into the upper chamber 501. And each kind of liquid may be configured with the separate upper liquid inlets, or a mixture of at least two kinds of liquid may be introduced into the upper chamber 501 through one upper liquid inlet.

In this embodiment, the upper liquid inlet 5011 is used to introduce two kinds of liquid into the upper chamber 501, notated as the first liquid and the second liquid, respectively. For example, the first liquid may be H₂O₂ and the second liquid may be H₂SO₄. Various ways of setting the upper liquid inlet 5011 will be described below in connection with FIGS. 13 to 15 by using the example of introducing the first liquid and the second liquid into the upper chamber 501.

### Upper Liquid Inlet 5011 Setup Method 1

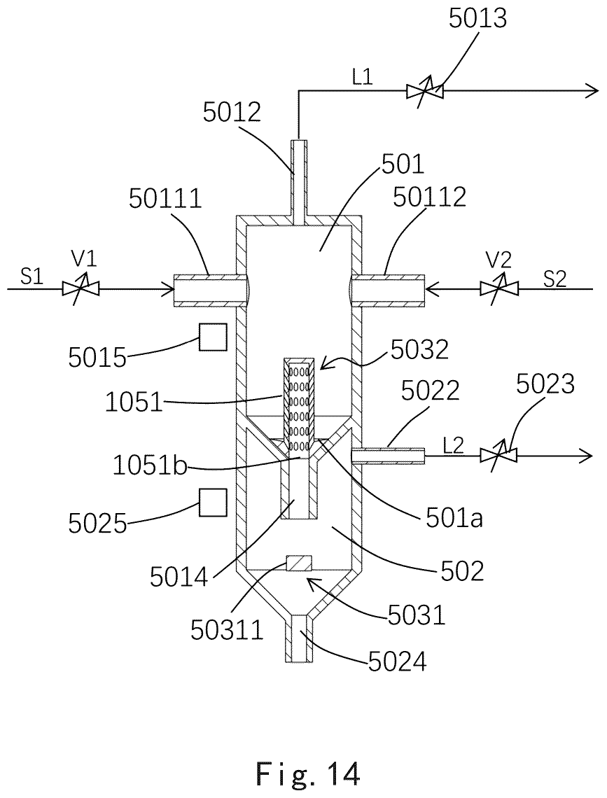

As shown in FIG. 13, the upper liquid inlet 5011 comprises a first upper liquid inlet 50111 and a second upper liquid inlet 50112. The first upper liquid inlet 50111 and the second upper liquid inlet 50112 may be provided at the same height or at different heights. In FIG. 13, the first upper liquid inlet 50111 is disposed higher than the second upper liquid inlet 50112. In FIG. 14, the first upper liquid inlet 50111 and the second upper liquid inlet 50112 are located at the same height. In method 1, the first liquid and the second liquid use the method of independent liquid intake so that the mixture of the first liquid and the second liquid is accomplished within the nozzle, which can shorten the distance between the mixture position and the liquid outlets, reduce the temperature loss, and obtain higher reaction temperature and reaction activity.

The first upper liquid inlet 50111 is connected to the first liquid supply line S1 for introducing the first liquid into the upper chamber 501, such as H₂O₂. The first liquid supply line S1 is provided with the first valve V1 for switching the first liquid supply line S1 between supplying and stopping the supply of the first liquid.

The second upper liquid inlet 50112 is connected to the second liquid supply line S2 for introducing the second liquid into the upper chamber 501, such as H₂SO₄. The second liquid supply line S2 is provided with the second valve V2 for switching the second liquid supply line S2 between supplying and stopping the supply of the second liquid.

### Upper Liquid Inlet 5011 Setup Method 2

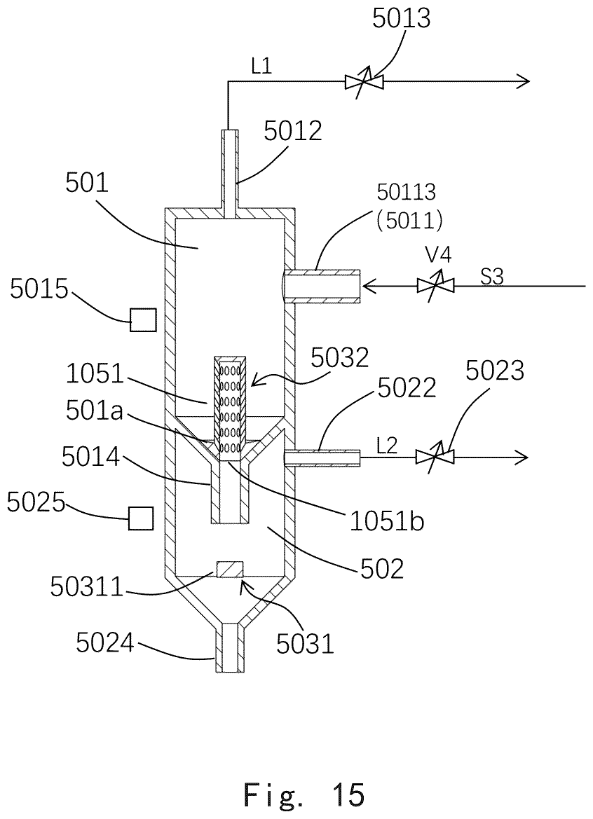

As shown in FIG. 15, the upper liquid inlet 5011 includes a mixture liquid entrance 50113. The first liquid and the second liquid enter the nozzle after being mixed outside the nozzle. Specifically, as shown in FIG. 15, the mixture liquid entrance 50113 is connected to the mixture liquid line S3 for introducing a mixture of the first liquid and the second liquid into the upper chamber 501. The first liquid and the second liquid may be supplied into the upper chamber 501 after being mixed in the mixing line S3. In addition, a mixer (not shown in the figure) may be provided on the mixing line S3, and the first liquid and the second liquid are mixed by the mixer before being supplied into the upper chamber 501. The liquid mixing line S3 is configured with a fourth valve V4 for switching the liquid mixing line S3 between supplying and stopping the mixture of the first liquid and the second liquid.

### Upper Liquid Inlet 5011 Setup Method 3

The upper liquid inlet 5011, on the basis of method 1 or method 2, can also adopt the method of tangential liquid intake, that is, the upper liquid inlet 5011 is tangential to the sidewall of the upper chamber 501. When the first liquid and the second liquid enter the upper chamber 501 in a tangential direction, the liquid will make a rotational movement within the upper chamber 501. And under the action of centrifugal force, better mixture and exhaust effects can be obtained.

For example, in FIGS. 13 and 14, the first upper liquid inlet 50111 and the second upper liquid inlet 50112 are tangential to the sidewall of the upper chamber 501. The first liquid and the second liquid enter the upper chamber 501 in a tangential direction respectively, and the first liquid and the second liquid rotate in the same direction after entering the upper chamber 501. Besides, in FIG. 15, the mixture liquid entrance 50113 is tangential to the sidewall of the upper chamber 501, so that the mixture of the first liquid and the second liquid enters the upper chamber 501 in a tangential direction.

The upper exhaust port 5012 is provided in an upper portion of the upper chamber 501 and is connected to the first exhaust line L1 for discharging gas from the upper chamber 501. The first exhaust line L1 is configured with an upper adjusting valve 5013, and the liquid level height in the upper chamber 501 can be regulated by changing the opening degree of the upper adjusting valve 5013.

The upper liquid level sensor 5015 is used to detect the liquid level height in the upper chamber 501 and send the detection signal to the controller. The controller, the upper liquid level sensor 5015, and the upper adjusting valve 5013 form a first closed-loop control to maintain the liquid level within the upper chamber 501 at a predetermined height. Wherein, the upper liquid level sensor 5015 may be selected as a contact-type liquid level sensor or a non-contact liquid level sensor, preferably a non-contact liquid level sensor, such as an optical liquid level sensor or a capacitive liquid level sensor. As shown in FIGS. 13 to 16, the upper liquid level sensor 5015 is a non-contact liquid level sensor that is detachedly disposed on one side of the nozzle.

The predetermined height of the liquid level in the upper chamber 501 serves as an input parameter, which can be reasonably set according to the process requirement as well as the nozzle structure. In embodiment 1, the predetermined height of the liquid level within the upper chamber 501 is set higher than the upper liquid inlet 5011, so that when the fresh liquid supplied by the upper liquid inlet 5011 enters into the upper chamber 501, the fresh liquid flows directly into the original liquid in the upper chamber 501, which is conducive to maintaining a stable liquid level and realizing stable liquid supply. In another embodiment, the predetermined height of the liquid level in the upper chamber 501 is set lower than the upper liquid inlet 5011, so that when the fresh liquid supplied by the upper liquid inlet 5011 enters the upper chamber 501, the fresh liquid directly contacts the gas phase above the liquid surface of the upper chamber 501. A portion of the gas generated in the fresh liquid will not be involved in the liquid phase, and the portion of the gas does not need to overcome the escape resistance at the gas-liquid interface, which is more favorable for gas-liquid separation, realizing a better exhaust effect.

The upper liquid outlet 5014 is provided between the upper chamber 501 and the lower chamber 502 for introducing the mixture of the first liquid and the second liquid within the upper chamber 501 into the lower chamber 502.

### Lower Chamber 502

Referring to FIGS. 13 to 16, the lower chamber 502 includes a lower exhaust port 5022, a lower liquid outlet 5024, and a lower liquid level sensor 5025. The lower chamber 502 is located below the upper chamber 501, and the upper and lower chambers 502 are connected through the upper liquid outlet 5014. The lower liquid outlet 5024 is provided in a lower portion of the lower chamber 502 for discharging a mixture of the first liquid and the second liquid from the lower chamber 502 for treatment of the substrate.

The lower exhaust port 5022 is provided in an upper portion of the lower chamber 502, connected to the second exhaust line L2 for discharging gas from the lower chamber 502. The second exhaust line L2 is configured with a lower conditioning valve 5023, and the height of the liquid level in the lower chamber 502 can be regulated by changing the opening degree of the lower conditioning valve 5023.

The lower liquid level sensor 5025 is used to detect the liquid level height within the lower chamber 502 and send the detection signal to the controller. The controller, the lower liquid level sensor 5025, and the lower conditioning valve 5023 form a second closed-loop control to maintain the liquid level within the lower chamber 502 at a predetermined height. Similarly, the lower liquid level sensor 5025 may be selected as a contact-type liquid level sensor or a non-contact liquid level sensor, with the non-contact liquid level sensor being preferred. The predetermined height of the liquid level within the lower chamber 502 serves as an input parameter, which can be reasonably set according to the process requirement and the nozzle structure.

In this embodiment, the nozzle adopts a dual-chamber design to realize two-stage exhaust, which can achieve better exhaust effect and make the liquid supply stability more reliable. Specifically, when the first liquid and the second liquid are supplied to the upper chamber 501, part of the gas in the liquid will be discharged from the upper exhaust port 5012 to complete the first exhaust. Then, the mixture of the first liquid and the second liquid enters the lower chamber 502, and the other part of the gas in the liquid will be discharged from the lower exhaust port 5022 to complete the second exhaust. Through two exhausts, the gas content in the liquid ejected from the nozzle can be significantly reduced, realizing stable liquid supply.

In addition, a separating section is provided in at least one of the upper chamber 501 and the lower chamber 502. The separating section is provided above the liquid outlet of the chamber in which it is located. The separating section promotes gas-liquid separation on the one hand, and inhibits gas from being discharged from the liquid outlet of the corresponding chamber on the other hand. In this embodiment, the separating section is either the plate-like separating section 5031 or the cylinder-like separating section 5032, and the separating sections of both structures will be described below. As shown in FIGS. 13 to 16, the cylinder-like separating section 5032 is provided in the upper chamber 501, and the plate-like separating section 5031 is provided in the lower chamber 502. It should be noted that the specific forms of the provision of the separating sections in the upper chamber 501 and the lower chamber 502 are not limited to the examples in FIGS. 13 to 16. For example, both the upper and the lower chambers are provided with the cylinder-like separating sections 5032; or both the upper and the lower chambers are provided with the plate-like separating sections 5031; or the cylinder-like separating section 5032 is provided within the upper chamber 501 and no separating portion is provided within the lower chamber 502, etc.

### Plate-like Separating Section 5031

The plate-like separating section 5031 includes a plate board 50311, which is provided above a liquid outlet of the chamber in which it is located. In this embodiment, as shown in FIGS. 13 to 16, the plate-like separating section 5031 is provided in the lower chamber 502, and the plate board 50311 is provided above the lower liquid outlet 5024 of the lower chamber 502. Specifically, the plate board 50311 is spaced apart from the lower liquid outlet 5024 in a height direction, and when viewed from top to bottom, the plate board 50311 at least partially blocks the lower liquid outlet 5024, thereby playing a certain intercepting and separating effect on the bubbles entrained in the liquid, and preventing the bubbles from being discharged with the liquid from the lower liquid outlet 5024.

### Cylinder-like Separating Section 5032

The cylinder-like separating section 5032 includes a cylinder body 1051, as seen FIGS. 4(a) to 4(d). A plurality of slanted holes 1052 are provided on the sidewall of the cylinder body 1051, and the bottom 1051b of the cylinder body 1051 is open and connected to the liquid outlet of the chamber in which it is located. A plurality of slanted holes 1052 are provided in an inclined upward direction when viewed from the inner side of the cylinder body 1051 to the outer side. The angle between the slanted holes 1052 and the vertical direction is from 15° to 75°, for example from 30° to 60°. When the liquid from the outer side of the cylinder body 1051 enters the inner side of the cylinder body 1051 through the slanted holes 1052, the vast majority of the gas will float upward due to the resistance of the slanted holes 1052 and will not be able to enter the inner side of the cylinder body 1051. The gas can be discharged through the exhaust port of the chamber after the gas has escaped from the liquid, so as to realize gas-liquid separation and improve the stability of the liquid supply.

As shown in FIGS. 13 to 16, a diversion surface 501a is provided at the bottom of the chamber where the cylinder body 1051 is located, and the diversion surface 501a is inclined downward towards the direction of the cylinder body 1051. The lowest row of slanted holes 1052 on the cylinder body 1051 are connected to the lowest point of the diversion surface 501a to avoid liquid accumulation in the nozzle.

The top 1051a of the cylinder body 1051 may have a number of different configurations, as can be seen in FIGS. 4(a) to 4(d). The top 1051a of the cylinder body 1051 is sealed (as shown in FIG. 4(a)), or the top 1051a of the cylinder body 1051 is open (as shown in FIG. 4(b)), or the top 1051a of the cylinder body 1051 is provided with at least one through-hole 1053 (as shown in FIG. 4(c) and FIG. 4(d)), wherein the through-hole 1053 is either a vertical hole or angled towards the exhaust port.

In this embodiment, as shown in FIGS. 13 to 16, the cylinder-like separating section 5032 is provided in the upper chamber 501. The bottom 1051b of the cylinder body 1051 is open and connected to the upper liquid outlet 5014. The plate-like separating section 5031 is provided in the lower chamber 502 and above the lower liquid outlet 5024. The first liquid and the second liquid enter the upper chamber 501 through the upper liquid inlet 5011. Thereafter, the mixture of the first liquid and the second liquid enters the inner side of the cylinder body 1051 by a plurality of slanted holes 1052 on the sidewall of the cylinder body 1051. During the above progress, the mixture flows downwardly into the inner side of the cylinder body 1051 along the slanted holes 1052, and the gas entrained in the mixture floats upwardly and is discharged from the upper exhaust port 5012, completing the first exhaust. The mixture flows from the inner side of the cylinder body 1051 to the lower chamber 502 through the upper liquid outlet 5014, then the mixture flows to the lower liquid outlet 5024. During the above progress, the remaining gas (or newly generated gas) entrained in the mixture is intercepted by the plate board 50311 and moves in a backward direction to the mixture. The gas floats upwardly and is discharged again through the lower exhaust port 5022, completing the second exhaust. The mixture is sprayed downwardly to the surface of the substrate through the lower liquid outlet 5024.

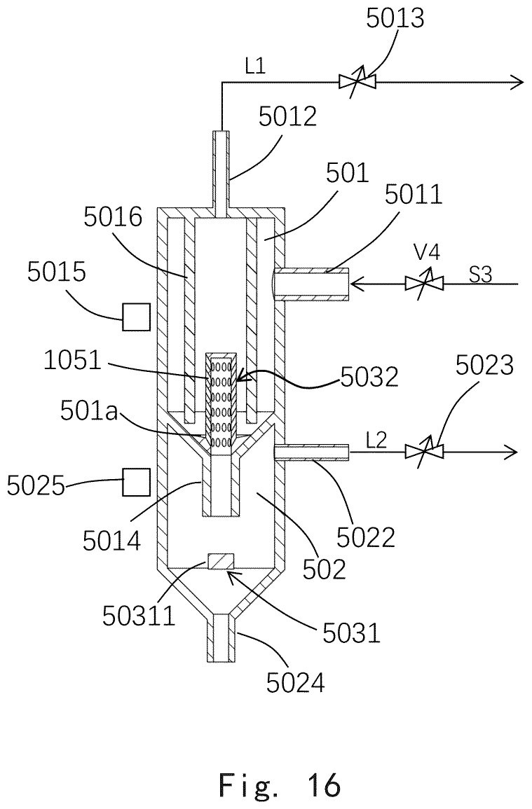

In addition, as shown in FIG. 16, a buffer board 5016 blocking the upper liquid inlet 5011 is provided in the upper chamber 501, and the buffer board 5016 is spaced apart from the upper liquid inlet 5011. The buffer board 5016 can play a buffering role for the first liquid and the second liquid entering the upper chamber 501 through the upper liquid inlet 5011, improving the stability and reliability of the nozzle liquid supply.

### Fifth Embodiment

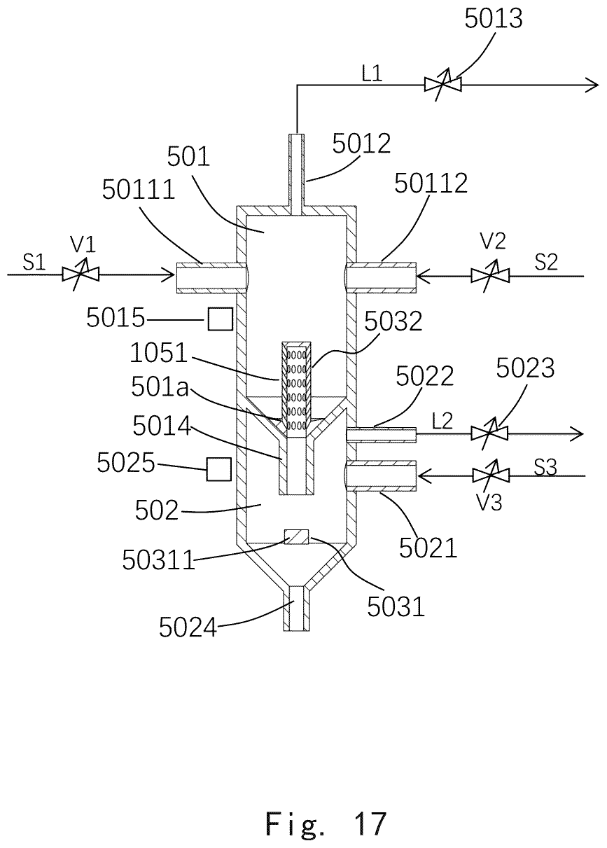

Referring to FIG. 17, the present embodiment provides a liquid supply device, which differs from embodiment 4 in that the lower chamber 502 further comprises a lower liquid inlet 5021 provided on the sidewall of the lower chamber 502. The lower liquid inlet 5021 serves as a replenishment inlet and is connected to the third liquid supply line S3 for introducing liquid, such as the first liquid and/or the second liquid. The third liquid supply line S3 is provided with a third valve V3 for switching the third liquid supply line S3 between supplying and stopping the supply of the first liquid and/or the second liquid. In this embodiment, the lower liquid inlet 5021 may be provided to be tangential to the sidewall of the lower chamber 502, for allowing the first liquid and/or the second liquid to enter the lower chamber 502 in a tangential direction. Alternatively, in this embodiment, the upper chamber 501 and/or the lower chamber 502 may be provided with a buffer plate (not shown in FIG. 17) that shields the liquid inlets of the corresponding chamber, and the buffer plate is spaced apart from the liquid inlets of the corresponding chamber.

It should be noted that in embodiment 5, the same structure as in embodiment 4 is attached with the same accompanying drawing designations, and the description is omitted.

In embodiment 1, the first liquid is H₂O₂ and the second liquid is H₂SO₄, and the lower liquid inlet 5021 is used to introduce H₂O₂ into the lower chamber 502. During the process operation, H₂SO₄ and H₂O₂ need to be mixed and supplied to the surface of the substrate in a predetermined ratio to clean the substrate. In this embodiment, H₂SO₄ and H₂O₂ are supplied to the upper chamber 501 in a first proportion to obtain a premixed liquid of H₂SO₄ and H₂O₂ with a first proportion. The premixed liquid enters the lower chamber 502 and is mixed for a second time with the H₂O₂ that supplied to the lower chamber 502, so as to obtain a mixture of H₂SO₄ and H₂O₂ with a pre-determined proportion. Then the mixture is sprayed onto the surface of substrate by the lower liquid outlet 5024.

This embodiment adopts a two-time mixture mode. Compared to the single-time mixture mode, the two-time mixture mode can reduce the consumption of H₂O₂ and the speed of bubble generation, which is more favorable for discharging bubbles and reducing the gas content in the liquid sprayed from the nozzle. In addition, the two-time mixture mode can increase the temperature of mixture and the concentration of carboxylic acid, helping to obtain a higher reaction temperature and reaction activity, improving the etching efficiency.

In addition, in this embodiment, the second closed-loop control constituted by the controller, the lower liquid level sensor 5025, and the lower conditioning valve 5023 maintains the liquid level within the lower chamber 502 at a predetermined height, and setting the same as the predetermined height of the liquid level in the upper chamber 501. The predetermined height of the liquid level within the lower chamber 502 serves as an input parameter that can be reasonably set according to the process requirement and the nozzle structure. In an embodiment, the predetermined height of the liquid level within the lower chamber 502 is set higher than the lower liquid inlet 5021. In another embodiment, the predetermined height of the liquid level within the lower chamber 502 is set lower than the lower liquid inlet 5021. In order to balance the exhaust efficiency and stable liquid supply, in an embodiment, the predetermined height of the liquid level within the upper chamber 501 is set lower than the upper liquid inlet 5011, and the predetermined height of the liquid level within the lower chamber 502 is set higher than the lower liquid inlet 5021.

The execution of the SPM cleaning process for the substrate using the liquid supply device proposed in this embodiment will be described in detail below in connection with FIG. 17. SPM is a mixture of H₂SO₄ and H₂O_{2.}

Step S1, H₂O₂ pre-supply stage (Pre-H₂O₂): The third valve V3 is turned on, and the first valve V1 and the second valve V2 are turned off. H₂O₂ is supplied to the lower chamber 502 of the nozzle to supply H₂O₂ to the surface of the substrate for cleaning the substrate, and to maintain a stable level of the liquid in the lower chamber 502. Wherein, the opening degree of the lower conditioning valve 5023 is regulated by the controller according to the detection signal of the lower liquid level sensor 5025, so as to maintain the stability of liquid level in the lower chamber 502.

Step S2, SPM supply stage (SPM): The first valve V1, the second valve V2, and the third valve V3 are turned on to provide H₂SO₄ and H₂O₂ to the upper chamber 501 of the nozzle on the one hand, and to supply H₂O₂ to the lower chamber 502 of the nozzle on the other hand. The liquid level within the upper chamber 501 and the lower chamber 502 is maintained at a stable level. The liquid in the upper chamber 501 is mixed with the liquid in the lower chamber 502 and then supplied to the surface of the substrate for cleaning. Wherein, the opening degree of the upper adjusting valve 5013 is regulated by the controller according to the detection signal of the upper liquid level sensor 5015, so as to maintain the stability of liquid level in the upper chamber 501. The opening degree of the lower conditioning valve 5023 is regulated by the controller according to the detection signal of the lower liquid level sensor 5025, so as to maintain the stability of liquid level in the lower chamber 502.

Step S3, H₂O₂ post-supply stage (Post-H₂O₂): The first valve V1 and the second valve V2 are turned off, and the third valve V3 remains turned on, that is, the upper chamber 501 of the nozzle is cut off the supply of H₂SO₄ and H₂O₂, and the lower chamber 502 of the nozzle continues to be supplied with H₂O₂. The surface of substrate is supplied with H₂O₂ to replace the mixture of H₂SO₄ and H₂O₂ on the surface of substrate. After cutting off the supply of the H₂SO₄ and H₂O₂ to the upper chamber 501 of the nozzle, the control of the liquid level height in the upper chamber 501 is stopped while maintaining the liquid level stability in the lower chamber 502. At the same time, the upper adjusting valve 5013 is in a state of normally turned on. Wherein, the controller regulates the opening degree of the lower conditioning valve 5023 according to the detection signal of the lower liquid level sensor 5025, so as to maintain the stability of liquid level within the lower chamber 502.

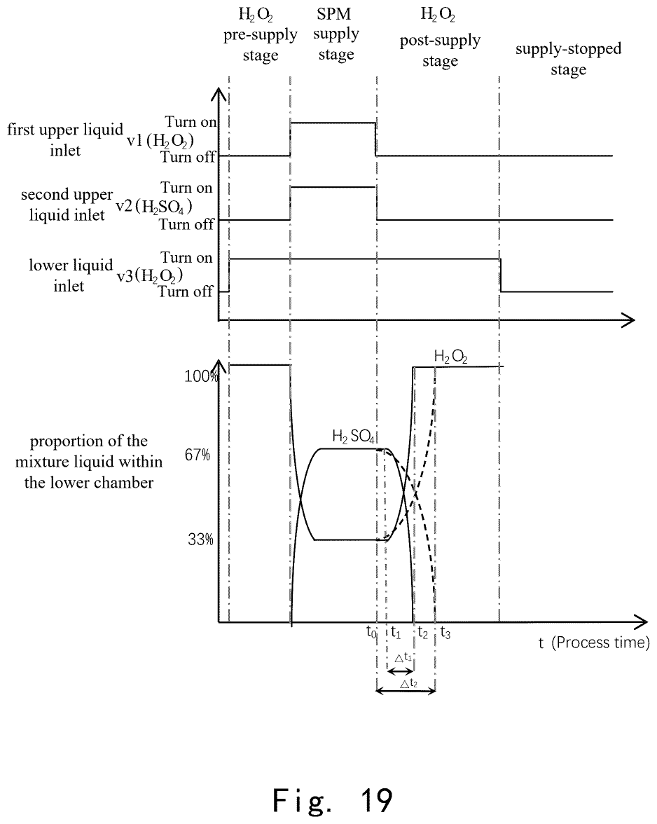

FIG. 19 illustrates a timing diagram of the liquid inlet valve action of the nozzle in the SPM cleaning process and a timing diagram of the change in the ratio of the mixture within the lower chamber 502. For clarity of description, the residual liquid depletion zone is defined as the time period from cutting off the liquid inlet to the upper chamber 501 until the residual liquid in the upper chamber 501 is emptied. In FIG. 19, to is the time when the upper chamber 501 is cut off from the liquid intake, at which time the first valve V1 and the second valve V2 are turned off. t1 is the time when the residual liquid in the upper chamber 501 is emptied without controlling the residual liquid discharge rate. The time period of t0~t1 is the residual liquid depletion zone without controlling the residual liquid discharge rate, and in the residual liquid depletion zone, the concentrations of the H₂SO₄ and the H₂O₂ in the lower chamber 502 are briefly maintained at the same concentrations as in SPM supply stage, which can be seen by the thick solid line in the time period of t0 to t1 in FIG. 19. After the residual liquid is emptied from the upper chamber 501, the concentration of H₂O₂ in the lower chamber 502 rapidly changes from the starting concentration (e.g., 33%) to 100% in a very short period of time, which can be seen by the thick solid line in the time period of t1~t2 in FIG. 19. Therefore, without intervention during the stage of emptying the residual liquid from the upper chamber 501, a sudden increase in the concentration of H₂O₂ may occur in the lower chamber 502. A large amount of gas is generated, causing the liquid to be sprayed out of the nozzle at once, and the liquid with gas bubbles impacts the surface of the substrate, which may cause the liquid to splash or damage the surface of the substrate.

### Sixth Embodiment

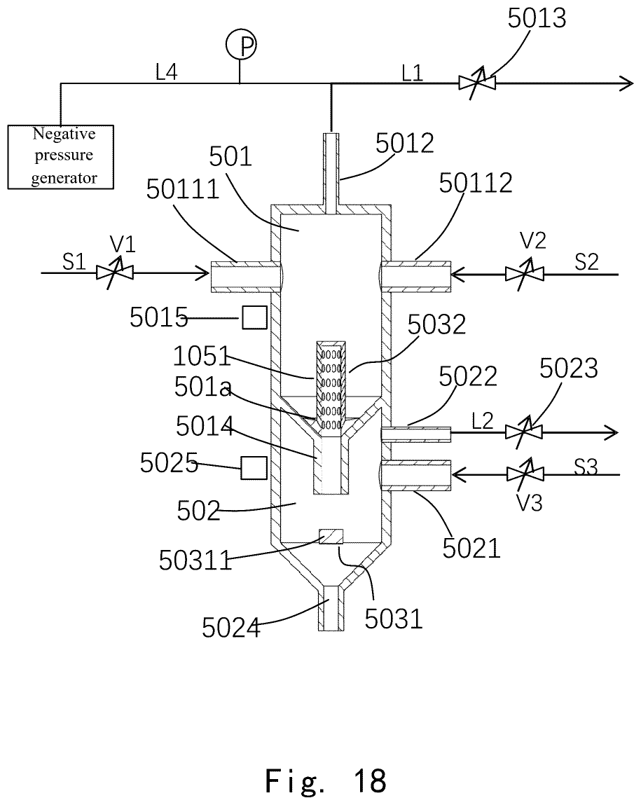

Referring to FIG. 18, this embodiment provides a liquid supply device, in order to solve the problem proposed in embodiment 5 that liquid splashing and substrate surface damage are caused by not controlling the discharge rate of residual liquid from the residual liquid depletion zone of the upper chamber 501. The present embodiment differs from embodiment 5 in that the liquid supplying device also includes a suction line L4, which connects the upper exhaust port 5012 to a negative pressure generator for reducing the pressure within the upper chamber 501 after the upper chamber 501 is cut off from the liquid intake. The discharge rate of the residual liquid flow from the upper chamber 501 to the lower chamber 502 is mainly affected by the gravity and the pressure difference between the upper and lower chambers. Therefore, by reducing the pressure within the upper chamber 501, the pressure difference between the upper and lower chambers is increased, thereby increasing the resistance to the descent of the residual liquid within the upper chamber 501, further reducing the discharge rate of the residual liquid within the upper chamber 501 flowing to the lower chamber 502. A pressure detector P may be provided on the suction line L4 to detect the pressure within the upper chamber 501 in real time.

In FIG. 19, the time period of t0~t3 is the residual liquid depletion zone in the case of controlling the discharge rate of the residual liquid. The dotted line in the time period of t0~t3 indicates the relationship between the concentrations of H₂SO₄ and H₂O₂ in the lower chamber 502 in the case of controlling the discharge rate of the residual liquid over time. Δt1 is the time taken for the H₂O₂ concentration to rise from the starting concentration of 33% to 100% when the rate of discharge of residual liquid from the upper chamber 501 is not controlled. Δt2 is the time taken for the H₂O₂ concentration to rise from the starting concentration of 33% to 100% when the rate of discharge of residual liquid from the upper chamber 501 is controlled. The Δt2 period is longer compared to the Δt1 period. In this embodiment, by controlling the slow discharge of residual liquid from the upper chamber 501 to the lower chamber 502, the discharge time of the residual liquid is prolonged. The time of change in the concentration of H₂O₂ is prolonged, so as to make the change in the concentration of H₂O₂ in the lower chamber 502 more gentle, thereby avoiding problems such as liquid splashing caused by a sudden rise in the concentration of H₂O₂.

A detailed description of the SPM cleaning process performed on the substrate using the liquid supply device proposed in this embodiment is described below. SPM is a mixture of H₂SO₄ and H₂O₂.

Step S1, H₂O₂ pre-supply stage (Pre-H₂O₂): The third valve V3 is turned on, and the first valve V1 and the second valve V2 are turned off. The H₂O₂ is supplied to the lower chamber 502 of the nozzle, so as to supply H₂O₂ to the surface of the substrate for cleaning the substrate. At the same time, the opening degree of the lower conditioning valve 5023 is regulated by the controller according to the detection signal of the lower liquid level sensor 5025, so as to maintain the stability of liquid level within the lower chamber 502.

Step S2, SPM supply stage (SPM): The first valve V1, the second valve V2, and the third valve V3 are turned on to provide H₂SO₄ and H₂O₂ to the upper chamber 501 of the nozzle on one hand, and H₂O₂ is supplied to the lower chamber 502 of the nozzle on the other hand. The stability of liquid level in the upper chamber 501 and the lower chamber 502 is maintained. The liquid in the upper chamber 501 is mixed with the liquid in the lower chamber 502. Then the mixture is supplied to the surface of the substrate for cleaning the substrate. Wherein, the opening degree of the upper adjusting valve 5013 is regulated by the controller according to the detection signal of the upper liquid level sensor 5015, so as to maintain the stability of liquid level in the upper chamber 501. The opening degree of the lower conditioning valve 5023 is regulated by the controller according to the detection signal of the lower liquid level sensor 5025, so as to maintain the stability of liquid level in the lower chamber 502.

Step S3, H₂O₂ post-supply stage (Post-H₂O₂): The first valve V1 and the second valve V2 are turned off, and the third valve V3 remains turned on, that is, the upper chamber 501 of the nozzle is cut off the supply of H₂SO₄ and H₂O₂, and the lower chamber 502 of the nozzle continues to be supplied with H₂O₂. The surface of substrate is supplied with H₂O₂ to replace the mixture of H₂SO₄ and H₂O₂ on the surface of substrate. At the same time, the opening degree of the lower conditioning valve 5023 is regulated according to the detection signal of the lower liquid level sensor 5025, so as to maintain the stability of liquid level in the lower chamber 502. The controlling on the liquid level height in the upper chamber 501 is stopped. The upper adjusting valve 5013 is turned off and the negative pressure generator is turned on, so as to reduce the pressure in the upper chamber 501 and maintain the pressure to a predetermined pressure. Compared to not controlling the discharge rate of the residual liquid in the upper chamber, after cutting off the liquid intake to the upper chamber 501, the pressure control of the upper chamber 501 can slow down the rate of descent of the residual liquid in the upper chamber 501, and prolong the time of change in the concentration of the mixture in the lower chamber 502. As shown in FIG. 19, the time of change in the concentration of H₂O₂ in the lower chamber changes from Δt1 to Δt2, thereby prolonging the time of change in the concentration of H₂O₂ in the lower chamber. Therefore, the H₂O₂ concentration changes more gently, helping to avoid liquid splashing and damage to the surface of the substrate caused by the sudden changes of concentration, reducing the cleaning effect.

Step S4, supply-stopped stage (Process end): The first valve V1, the second valve V2 and the third valve V3 are turned off. The controlling on the liquid level height in the lower chamber 502 is stopped. The negative pressure generator is turned off. The pressure control of the upper chamber is stopped. The upper exhaust valve 5013 is turned on. The upper adjusting valve 5013 and the lower adjusting valve 5014 are kept in the state of normally turned on.

The foregoing embodiments are merely illustrative of the principles and efficiencies of the present invention and are not intended to limit the present invention. Any person skilled in the art may modify or change the above embodiments without violating the spirit and scope of the present invention. Therefore, all equivalent modifications or changes made by people having ordinary knowledge in the art without departing from the spirit and technical ideas disclosed in the present invention shall be covered by the claims of the present invention.

1. A liquid supply device, having a nozzle with a cavity inside, the nozzle comprising:
a liquid inlet, for introducing liquid into the cavity;
a liquid outlet, provided in a lower portion of the cavity, for discharging liquid from the cavity;
an exhaust port, provided in an upper portion of the cavity, for discharging gas from the cavity;
a separating section, in the shape of a cylinder, located above the liquid outlet and located in the cavity, the separating section comprising a cylinder body with a plurality of slanted holes being provided on the sidewall of the cylinder body, the plurality of slanted holes being provided at an inclined upward direction when viewed from the inner side of the cylinder body to the outer side, and the bottom of the cylinder body being open and connected to the liquid outlet.

2. A liquid supply device according to claim 1, wherein the top of cylinder body is sealed, or the top of cylinder body is open, or the top of cylinder body is set with at least one through-hole.

3. A liquid supply device according to claim 2, wherein at least one through-hole is a vertical hole or inclined towards the direction of the exhaust port.

4. A liquid supply device according to claim 1, wherein the liquid inlet comprises:
a first liquid inlet, for introducing a first liquid into the cavity;
a second liquid inlet, for introducing a second liquid into the cavity.

5. A liquid supply device according to claim 1, wherein the liquid inlet comprises:
a mixture liquid inlet, for introducing a mixture of a first liquid and a second liquid into the cavity.

6. A liquid supply device according to claim 1, wherein the cavity is further provided with a buffer plate for blocking the liquid inlet, and a gap is provided between the buffer plate and the liquid inlet.

7. A liquid supply device according to claim 1, wherein the bottom of cavity is provided with a deflector surface being inclined downwardly towards the direction of the cylinder body, and the lowest row of slanted holes of cylinder body are connected to the lowest point of the deflector surface.

8. A liquid supply device, having a nozzle with a cavity inside, the nozzle comprising:
a liquid inlet, for introducing liquid into the cavity;
a liquid outlet, provided in a lower portion of the cavity, for discharging liquid and the second liquid from the cavity;
an exhaust port, provided in an upper portion of the cavity, for discharging gas from the cavity;
a liquid level sensor, for detecting the height of the liquid level in the cavity;
an exhaust line, connected to the exhaust port, for discharging gas from the cavity, the exhaust line being configured with a regulating valve;
a controller, connected to the liquid level sensor and the regulating valve via signals, to form a closed-loop control to maintain the liquid level in the cavity at a predetermined height.

9. (canceled)

10. A liquid supply device according to claim 8, wherein the liquid level within the cavity is maintained above the liquid inlet.

11. A liquid supply device according to claim 8, wherein the liquid level within the cavity is maintained below the liquid inlet.

12. A liquid supply device according to claim 8, wherein the nozzle further comprises a separating section provided within the cavity, and the separating section is located above the liquid outlet.

13. A liquid supply device according to claim 12, wherein the separating section is in the form of a plate, and the separating section comprises a plate body being disposed above the liquid outlet.

14. A liquid supply device according to claim 12, wherein the separating section is in the shape of a cylinder and comprises a cylinder body, a plurality of slanted holes are provided on the sidewall of the cylinder body, the plurality of slanted holes are provided inclined upwardly when viewed from the inner side of the cylinder body to the outer side, and the bottom of cylinder body is open and connected to the liquid outlet.

15. A liquid supply device according to claim 14, wherein the top of cylinder body is sealed, or the top of cylinder body is open, or the top of cylinder body is set with at least one through-hole.

16. A liquid supply device according to claim 15, wherein at least one through-hole is a vertical hole or inclined towards the direction of the exhaust port.

17. A liquid supply device according to claim 14, wherein the bottom of cavity is provided with a deflector surface being inclined downwardly towards the direction of the cylinder body, and the lowest row of slanted holes of the cylinder body are connected to the lowest point of the deflector surface.

18.-27. (canceled)

28. A liquid supply device according to claim 8, wherein
the liquid inlet is tangential to the sidewall of the cavity, for enabling liquid to enter the cavity of the nozzle in a tangential direction.

29. A liquid supply device according to claim 28, wherein the liquid comprises at least one kind of liquid, each kind of liquid is configured with a separate liquid inlet, or a mixture of at least two kinds of liquid is introduced into the cavity through a liquid inlet.

30.-50. (canceled)
